(19) United States
(12) Patent Application Publication
(10) Pub. No.: US 2010/0146949 A1
(43) Pub. Date: Jun. 17, 2010

(54) Vehicle power supply system

(75) Inventors: Richard Keith Stobart, Nottingham (GB); Weerasinghe Mudalige Sujith Rohitha Weerasinghe, Kent (GB)

Correspondence Address: James D Fornari;C/O Gersten Savage, 600 Lexington Avenue, New York, NY, 10022, US

(73) Assignee: THE UNIVERSITY OF SUSSEX, Brighton (GB)

(21) Appl. No.: 12/311,234

(22) PCT Filed: Sep. 25, 2007
(86) PCT No.: PCT/GB2007/003644

§ 371 Date: Feb. 11, 2010

(30) Foreign Application Priority Data
Sep. 25, 2006 (GB) 0618867.6

(51) Int. Cl. F01N 3/10; F01N 5/02; F02G 1/04; F02D 45/00; F02B 63/04; H01L 35/30

(52) U.S. Cl. 60/300; 60/320; 60/517; 701/102; 290/1 A; 136/205

(57) ABSTRACT

A vehicle power supply system comprises an internal combustion engine (1) and a steam generator (2) arranged in a “closed system”. Water, or another suitable working fluid, is supplied to the steam generator (2) whereupon it is heated using exhaust heat from the internal combustion engine (1). The steam that is generated is stored in a storage tank (3) until a later time, e.g. when the internal combustion engine (1) is not running, whereupon the steam is used to provide heat and/or power to vehicle. For example, the steam can be used to drive a generator (5), via an expander (4), to provide electricity for powering various electrical systems within the vehicle. Additionally, the hot exhaust (7) from the expander (4) can be supplied to a radiator (8) to provide heating for the vehicle cabin.

The present invention relates to a power supply system for vehicles and in particular to a power supply system for road vehicles.

It is common for large and medium (US class 8 and 6) trucks to idle their internal combustion engines even when they are not actually transporting goods. Such idling is generally to provide power for what is commonly referred to as “hotel load”, namely for the comfort of the driver when the vehicle is at rest. Such hotel load comprises, for example, the use of cabin and auxiliary equipment, climate control units (heating and cooling), etc. There may be as much as 5 hours per day idling time.

The need to idle a truck's engine to provide hotel load power can be a significant problem. For example, it consumes fuel and increases engine wear. Running an engine near idling is particularly inefficient. There are also issues with exhaust emissions and noise pollution caused by trucks idling to provide hotel load power.

There have accordingly been a number of proposals to try to reduce the need to use engine idling to provide power for hotel loads in vehicles such as trucks. For example, it is known to provide auxiliary power units, for example in the form of batteries, auxiliary generators, or fuel cells, to provide some or all of the power required for hotel loads. However, there are disadvantages to these arrangements as well. For example, in the case of batteries the engine will still need to be loaded to charge the batteries. Auxiliary generators, while more efficient than using the main internal combustion engine for generating electricity, still produce exhaust emissions and tend to have a limited lifespan.

The Applicants accordingly believe that their remains scope for improvements to power supply systems for vehicles, and in particular in relation to the provision of power for hotel loads in road vehicles, such as trucks.

According to a first aspect of the present invention, there is provided a power supply system for a vehicle, comprising:

an internal combustion engine;

means for using exhaust heat from the internal combustion engine to heat a working fluid; and

means for storing the heated working fluid whereby it may be used to provide heat and/or power for the vehicle at a later time.

According to a second aspect of the present invention, there is provided a method of operating a power supply system for a vehicle that includes an internal combustion engine, the method comprising:

using exhaust heat from the internal combustion engine to heat a working fluid; and

storing the heated working fluid whereby it may be used to provide heat and/or power for the vehicle at a later time.

In the present invention, the exhaust heat generated by an internal combustion engine is used to heat a working fluid, such as water. However, instead of simply using the heated fluid at that time to supplement the power of the engine, and/or to generate electricity, the heated fluid is stored for later use to provide power and/or heat for the vehicle.

Storing the heated working fluid in this way allows it, for example, and as will be explained further below, to be used at a later time to meet hotel load demands, such as for heating or electrical power generation. This can then be used to reduce engine idling time for hotel load demands, thereby, as discussed above, for example increasing efficiency, reducing exhaust emissions and reducing noise pollution.

In other words, in the present invention a working fluid accumulation arrangement is used to recover exhaust heat when the internal combustion engine is running, store it, and then provide the recovered (stored) energy to meet, e.g., hotel load demands at a later time, and, e.g., and in particular, when the internal combustion engine is not running.

Thus, according to a third aspect of the present invention, there is provided a method of operating a power supply for a vehicle that includes an internal combustion engine, the method comprising:

recovering exhaust heat when the internal combustion engine is running;

storing the recovered heat energy at least in part as heat energy; and

providing the stored heat energy at a later time to provide heat and/or power for the vehicle.

According to a fourth aspect of the present invention, there is provided a power supply system for a vehicle that includes an internal combustion engine, the system comprising:

means for recovering exhaust heat when the internal combustion engine is running;

means for storing the recovered heat energy at least in part as heat energy; and

means for providing the stored heat energy at a later time to provide heat and/or power for the vehicle.

As will be appreciated by those skilled in the art, these aspects of the present invention can and preferably do include any one or more or all of the preferred and optional features of the invention described herein, as appropriate. Thus, for example, the exhaust heat is preferably recovered by using it to heat a working fluid, such as water, and then stored by storing the heated working fluid. The recovered heat energy is similarly preferably used to provide power and/or heat when the internal combustion engine is not running.

The working fluid that is used and heated in the present invention may be any suitable such fluid. In a particularly preferred embodiment, the working fluid is water and thus the exhaust heat is used to heat water, most preferably to generate steam (which is then, preferably stored for later use, as discussed above). Water is a particularly convenient and efficient working fluid to use. However, other fluids, such as organic fluids, such as iso-pentane or R245ca could be used instead, or as well, if desired.

In the present invention, the working fluid (e.g. water) may be heated by the exhaust heat generated by the internal combustion engine (the heat rejected by the engine), and the exhaust (rejected) heat of the internal combustion engine may be recovered, in any suitable manner.

In a particularly preferred embodiment, the exhaust heat of the engine is recovered, and the working fluid is heated, by heat transfer from the engine exhaust and/or engine exhaust gases. Thus, in a preferred embodiment, the working fluid is heated, and the heat energy is recovered by means of an arrangement, such as and preferably a heat exchanger arrangement, around the exhaust system of the internal combustion engine. Thus, the system of the present invention preferably comprises an exhaust gas heat exchanger arrangement for heating a working fluid using the (waste) exhaust heat of the internal combustion engine.

Other heating arrangements to capture and recover exhaust (waste) heat from the engine and to thereby heat the working fluid would, of course, be possible. For example, the heat of engine itself, such as from the combustion cylinders, could, as will be discussed further below, be used as well or instead to heat the working fluid, for example, and preferably, by circulating the working fluid around the engine in use, for example in the cooling jacket of the engine. Thus, in a preferred embodiment, the system of the present invention comprises an arrangement for or step of, circulating the working fluid around or over the engine, whereby the working fluid may be heated by the engine in use.

The working fluid is most preferably at least heated using the exhaust and/or exhaust gases of the engine. In a particularly preferred embodiment, as will be discussed further below, the working fluid is heated by both (e.g. by circulating it around both) the engine itself and the engine's exhaust system.

As will be appreciated by those skilled in the art, there will need to be a working fluid (e.g. water) supply that can be heated. This fluid supply can be provided as desired, but preferably there is a store or reservoir of working fluid (e.g. water) that can be provided for heating as required. Thus, the system preferably comprises a working fluid supply, preferably in the form of a water reservoir, which fluid can be provided to the heating means (e.g. exhaust heat exchanger) to be heated as required. Preferably a closed fluid supply system is used, i.e. in which heated fluid (e.g. water converted to steam) is returned (recycled) to the (cold) fluid supply (reservoir) once used. However, an open system in which the heated working fluid is not recycled could be used if desired.

Thus, in a particularly preferred embodiment, the working fluid heating and storage system is arranged as a “closed” system, i.e. so that there is a closed circuit of working fluid (e.g. water and steam) that can be continuously recirculated. Preferably the arrangement is such that if a predetermined or particular capacity of stored heated fluid (e.g. steam or water) is reached, any excess working fluid (e.g. steam or hot water) can be run through a continuous cycle (e.g. to generate electricity, as will be discussed further below), rather than being stored, and/or can be exhausted to the atmosphere.

In a particularly preferred embodiment, the working fluid (e.g. water) that is to be supplied to the (exhaust) heat exchanger to be heated is first preheated, e.g., and preferably, in the case of water, to a temperature approaching 100°C. This can be achieved as desired. In a particularly preferred arrangement, the fluid is preheated by circulating it around the internal combustion engine (e.g. and preferably in the cooling jacket of the engine). This helps to further recover exhaust (waste) heat energy of the engine.

The Applicants have further recognised that such an arrangement could be used in place of a conventional engine radiator arrangement for engine cooling purposes. In particular, rather than use an engine radiator, the engine heat can be transferred to the working fluid (which may be and preferably is thereafter further heated using the engine exhaust gases). In such an arrangement, a condenser could be used, if required, to allow recycling of the working fluid to maintain its engine cooling function.

Thus, in a preferred embodiment, there is a two-stage heating process, which preferably uses the heat of the engine, and then the heat of the exhaust, to heat the working fluid.

Thus, in a preferred embodiment where the working fluid comprises water, the system of the present invention comprises means for (or a step of) heating the water before it is supplied to the steam generating means (or step), preferably in the form of an arrangement for (or a step of) circulating the water around the internal combustion engine before it is supplied to the steam generating means (or step).

Once the working fluid has been heated (the exhaust heat has been recovered), it is, in the present invention, as discussed above, stored in some form for later use to provide power and/or heat for the vehicle. This storage can be performed in any appropriate and desired manner.

For example, the working fluid could be, and in one embodiment preferably is, stored in gaseous form. Thus, in the case of water, where steam is generated, the generated steam could be, for example, and in one preferred embodiment is, stored as “steam” for later use, e.g., in a suitable steam storage vessel, such as a reservoir or accumulator.

It would also be possible to store the heated working fluid in liquid form. Thus, in the case of water, e.g., where steam is generated, the generated steam could be condensed and the resulting hot water then stored (again in a suitable vessel such as a reservoir or tank). This may be more appropriate or desirable where the heated working fluid (e.g. steam) is, as discussed below, used immediately to, e.g., drive the vehicle or a generator and can thereafter be condensed and stored as hot liquid (e.g. hot water). Thus, in one preferred embodiment, the heated working fluid is stored as hot liquid (e.g. water) for later provision of heat and/or power for the vehicle.

Thus, in a preferred embodiment, the system of the present invention comprises means for or a step of converting the heated working fluid to a hot liquid (e.g. converting the generated steam to hot water) and storing the hot liquid (e.g. water) for later use to provide heat and/or power for the vehicle. Most preferably, a condenser for condensing the heated working fluid (e.g. steam) to provide hot liquid (e.g. water) is provided. These arrangements may be desirable where, e.g., the heated working fluid is to be used to provide internal cabin heating of the, vehicle (as in that case, it would be preferable to circulate hot liquid through the cabin radiator(s)).

In a particularly preferred embodiment, the heated working fluid is heated to (and preferably initially stored at) saturation conditions (i.e. just at the onset of boiling). It is preferably then maintained at this (saturation) condition (temperature). As is known in the art, the working fluid at saturation conditions will in practice be mostly (e.g. 90%) liquid, with the remainder as gas.

In a particularly preferred embodiment, the system of the present invention comprises means for or a step of storing both hot gas and hot liquid generated via the exhaust gas heat recovery. For example, in the case of water being the working fluid, steam could be stored and then when the steam has been used, any residual hot water could be stored for later use as well. Thus, the system of the present invention preferably comprises a step of or means for storing gas (e.g. steam) generated using exhaust heat from the internal combustion engine and a step of or means for storing hot liquid (e.g. water) resulting from the hot gas (e.g. steam) generated using the exhaust heat from the internal combustion engine.

In a particularly preferred such arrangement, there is a two-stage storage arrangement, with hot liquid (e.g. water) storage arranged downstream of a gas (e.g. steam) storage arrangement. Most preferably, there is a store of higher pressure gas (e.g. steam), and also a store of lower pressure hot liquid (e.g. water). This facilitates, for example, using the generated gas (e.g. steam) both to generate electricity and for heating purposes, as will be discussed further below. In these arrangements, hot gas (e.g. steam) from the gas (e.g. steam) store can preferably be fed to make up the hot liquid (e.g. water) store as and when required, for example in the case of low temperature in the hot liquid (e.g. water) storage. This facilitates maintaining the hot liquid storage at a desired temperature (e.g. a desired heating temperature).

In these arrangements, the higher pressure, hot “gas” storage arrangement preferably in fact stores the heating working fluid in part as a liquid and in part as a gas, and preferably at saturation conditions (and thus as a combination of liquid and gas), as discussed above.

The heated working fluid (e.g. steam and/or hot water) may be stored in any appropriate manner. It is preferably stored in an appropriate reservoir or reservoirs or accumulator or accumulators provided in association with the power supply system on or in the vehicle. The storage means (e.g. reservoir) is preferably thermally lagged, so that its heat will be maintained, e.g. for several hours, after main engine shut down. The heated working fluid (e.g. steam and/or hot water) is preferably stored at a constant, e.g. selected, temperature. As discussed above, it is preferably stored at least at one point at saturation conditions.

Where steam is being stored, it is preferably stored at relatively high pressure, such as 5 to 50 bar. This helps make the storage more compact. However, the storage pressure is preferably also selected so as to achieve, e.g., efficient steam flow and heat exchange. As will be appreciated by those skilled in the art, the storage pressure will affect these factors and so a suitable trade-off between, e.g., efficiency and reservoir size and construction is preferably made.

For example, storing the heated working fluid at higher pressure will provide higher efficiency where it is used to drive an expander (see below) to generate electricity, and decrease the size of the system for a given energy storage capacity. On the other hand, higher pressure storage will require a heavier (more massive) system, with commensurate increased material and production costs.

A lower operating pressure will provide higher heat transfer rates of the exhaust heat to the working fluid. This is because for a given exhaust heat temperature, lower working fluid pressure implies a lower temperature and therefore a greater temperature difference with the exhaust heat (and thus a higher heat transfer rate).

The Applicants have accordingly recognised that by changing the operating pressure, the heat transfer rate, for example, can be controlled. Similarly, if the pressure is increased when the heated fluid is discharged to generate, e.g., electricity, the expansion and electricity generation process can be made more efficient. Thus, in a particularly preferred embodiment, the operating pressure (e.g. storage and/or working pressure) of the working fluid can be varied in use. Thus, the system of the present invention preferably comprises means for or a step of varying the operating pressure of the working fluid in use.

As discussed above, and as will be appreciated by those skilled in the art, the “gas” (e.g. “steam”) storage will typically actually store the heated working fluid (e.g. water) as a mixture of liquid and gas (e.g. water and steam), e.g., depending on the pressure and temperature of the storage. Thus references herein to storing the heated working fluid (e.g. generated steam) as a “gas” should be understood to include storing a combination of gas and liquid (e.g. steam and water), i.e. to imply that at least some of the heated working fluid will be in a gaseous form (e.g. some of the heated water will be in the form of steam).

As discussed above, the stored heated working fluid (e.g. steam, and/or water) and/or recovered heat is to be used at a later time for the provision of power and/or heat for the vehicle. Thus, in a preferred embodiment, the present invention further includes means for or a step of using the stored heated working fluid and/or recovered heat to provide power and/or heat for the vehicle. This can preferably be done, and is preferably done, when the internal combustion engine is not running. In other words, the stored heated working fluid (e.g. steam and/or hot water), and/or recovered heat, preferably can be and preferably is used to provide power and/or heat independently of, and without the simultaneous operation of, the internal combustion engine of the vehicle.

The stored heated working fluid and/or recovered heat can be used to provide power and/or heat for the vehicle in any desired and suitable manner. For example, it could be used directly to provide propulsion for the vehicle.

In a particularly preferred embodiment, the heated working fluid (e.g. generated and/or stored steam) is used to generate electricity. In these arrangements, the working fluid (e.g. steam) can be used to generate electricity in any suitable manner. For example it could be and preferably is used to drive a generator (e.g. a rotary or reciprocating (linear) generator), preferably via an expander. The generated electricity may be used directly to power electrical units or systems of the vehicle, or it may be used to, e.g., charge a battery (which may then be used to power the electrical units (systems) of the vehicle). Such electricity generation can preferably be, and is preferably, performed when the internal combustion engine is not running.

In a preferred embodiment where the heated working fluid (e.g. steam) can be used to generate electricity, the heated working fluid can be and preferably is used also or instead to generate electricity while the internal combustion engine is running, i.e. such that electricity can be generated continuously by the working fluid system while the internal combustion engine (the primary engine) is running, if desired.

In these arrangements where the (stored) heated working fluid (e.g. steam) is used to generate electricity, the exhaust working fluid (e.g. steam and/or water) from the generator (e.g. expander) is preferably captured and pumped back for future use in the working fluid system. It could, e.g., be captured and fed back to the working fluid (e.g. steam generation) storage system. Alternatively or additionally, it could be and preferably is provided to a hot fluid, e.g., liquid, (e.g. water/steam) storage arrangement, as discussed above, that can then, e.g., be used for heating purposes (as will be explained further below).

In a particularly preferred embodiment, the (stored) heated working fluid (e.g. steam and/or hot water) can also or instead be used and is preferably also or instead used to provide heating to the vehicle's cabin. This could be done in any appropriate and suitable manner. For example, and preferably, the stored heated fluid (e.g. steam and/or hot water) could be provided to a radiator heater for cabin heating. In such an arrangement, the output from the cabin heater (e.g. radiator) may, e.g., be returned to the cold working fluid supply for later use to be heated again, or run through a continuous cycle around the heating circuit. Again, this arrangement can preferably be used both while the main engine is running and when the main engine is stopped. In the former case at least, it is preferably operated on a continuous cycle.

In a particularly preferred embodiment, the generated (and, e.g., stored) heated working fluid can be used both to generate power, e.g. and preferably electricity, and to provide heating. It can preferably do so simultaneously, and also independently of each other, e.g., and preferably under the control of the driver (user).

In a particularly preferred such arrangement, the exhaust heated working fluid (e.g. steam) from the electricity generation is, as discussed above, captured (and, e.g., condensed) and then stored and used, e.g., as hot liquid.(e.g. water), for use to provide heating, if and when desired.

In a particularly preferred embodiment of the present invention, the generated and stored heated working fluid (e.g. steam and/or hot water) can be used to heat the vehicle's (exhaust) catalyst. This can be achieved by providing, for example, an appropriate heat exchanger/fluid circulation arrangement around the catalyst, to which stored heated working fluid (e.g. steam or hot water) may be fed as and when desired. Preferably the arrangement is such that the pressure and flow of the heated working fluid (e.g. steam and/or hot water) through the catalyst heating circuit can be controlled, for example to provide temperature regulation of the catalyst. This could be achieved using, for example, an appropriate arrangement of control valves.

In a particular preferred embodiment of this arrangement of the present invention, the pressure of the working fluid (e.g. steam) to be supplied to heat the catalyst can be increased before it is supplied to the catalyst heating arrangement. This will increase the temperature of the fluid (e.g. steam), due to latent heat.

Using the stored heated working fluid to heat the engine's catalyst has a number of advantages. For example, it can be used to heat up the catalyst to its operating temperature before start-up of the engine, thereby, e.g., reducing light-off time, and emissions when the engine is started from cold. It could also be used, e.g., to help to maintain the catalyst at the desired operating temperature in use. This may allow, for example, less expensive catalysts to be used.

The heated working fluid (e.g. steam and/or hot water) used to heat the catalyst is preferably recirculated for subsequent re-use, e.g., to generate more steam. In a preferred embodiment it can be and is recovered and stored in a hot fluid storage arrangement for use to provide heating; as discussed above. Similarly, the heated working fluid could be and preferably is first used to generate electricity and then the exhaust working fluid captured and stored for use for catalyst heating.

It is believed that the use of a heated working fluid to provide heating to a catalyst of a vehicle may be new and advantageous in its own right. Thus, according to a fifth aspect of the present invention, there is provided a system for an internal combustion engine of a vehicle which includes a catalytic converter exhaust gas treatment arrangement, the system comprising:

means for using exhaust heat from the internal combustion engine to heat a working fluid; and

means for using the heated working fluid to heat the catalyst of the exhaust gas treatment arrangement.

According to a sixth aspect of the present invention, there is provided a method of operating an engine system of a vehicle which includes an internal combustion engine and a catalytic converter exhaust gas treatment arrangement, the method comprising:

using exhaust heat from the internal combustion engine to heat a working fluid; and

using the heated working fluid to heat the catalyst of the exhaust gas treatment arrangement.

As will be appreciated by those skilled in the art, these aspects of the invention can and preferably do include any one or more or all of the preferred and optional features of the invention described herein, as appropriate. Thus, for example, the heated working fluid is preferably stored and used at a later time to heat the catalyst and preferably when the internal combustion engine is not running. Similarly, the working fluid is preferably water, which is preferably heated to generate steam, and in that case the generated steam may be used as steam or in the form of hot water to heat the catalyst.

As well as the above described arrangements for using the hot working fluid generated in the system of the present invention, other arrangements would be possible. For example, it would also be possible to use the heated working fluid (e.g. steam) to provide additional propulsion (mechanical power) in parallel with the internal combustion engine while the engine is running, if desired. Similarly the working fluid driven generator and internal combustion engine could be run simultaneously to generate electricity, e.g., to charge a battery.

The generated and stored heated working fluid (e.g. steam and/or hot water) could also be injected into the cylinders of the internal combustion engine and/or the exhaust gas, for example to provide emissions control and/or management of exhaust gas after-treatment temperatures.

In another particularly preferred embodiment of the present invention, the power supply system is arranged such that a piston or pistons can be driven by the internal combustion engine or by heated working fluid, e.g., gas, such as steam, generated using exhaust heat, or by both the internal combustion engine and working fluid simultaneously. This facilitates having a hybrid, dual-media (fuel) power supply arrangement that can use whichever power source is available and/or suitable at any given time.

Such an arrangement can be achieved as desired. Most preferably the piston or pistons are arranged such that it or they can be driven from one side (in one direction) by the internal combustion engine and from the other side (in the other direction) by the heated working fluid (e.g. steam). The piston or pistons is or are preferably linearly reciprocating.

In a particularly preferred such embodiment, a free piston arrangement is used, i.e. in which the power stroke in one direction of the piston acts directly as the compression stroke for the movement in the opposite direction of the piston. In this case, there could, as is known in the art, be, in effect, two pistons mounted back-to-back, one driven in one direction by the internal combustion engine and one driven in the reverse direction by the working fluid (e.g. steam). However, in a preferred embodiment, there is a single, preferably linearly reciprocating piston, one side of which can be driven by the internal combustion engine, and the other side of which can be driven by the working fluid (e.g. and preferably steam).

A free piston arrangement is advantageous, inter alia, because of its flexibility and compactness.

In these arrangements, the side of the piston or pistons driven by the internal combustion engine preferably operates in the normal manner, i.e. following a conventional internal combustion cycle, such as the Otto or Diesel cycle.

The side of the piston or pistons driven by the working fluid (e.g. steam) similarly preferably operates using a conventional fluid (e.g. steam) expansion cycle. Most preferably a Rankine steam expansion cycle is used. An open-loop uniflow fluid (e.g. steam) expansion arrangement could be used. However, a closed loop, U-flow arrangement is preferred, as that facilitates more precision in control. Where a closed loop working fluid (e.g. steam) cycle is used, a condenser and pump may be provided to complete the loop arrangement.

In these arrangements, the piston or pistons can preferably be driven by the internal combustion engine alone. This may be desirable or necessary, e.g., where a working fluid (e.g. steam) supply is not available or not yet generated (e.g. on start-up of the engine). In this case, the values on the “working fluid” (e.g. “steam”) side of the piston or pistons are preferably kept closed to produce a spring action to move the piston or pistons backward after the expansion stroke.

The piston or pistons can preferably also or instead (and preferably also) be driven by the working fluid (e.g. steam) alone. In this case preferably only one side (the side not driven by the internal combustion engine) of the piston or pistons are driven by the working fluid, but it would also be possible for both sides of the piston to be driven by the working fluid with an appropriate arrangement of valves, etc., if desired. Driving the piston or pistons by the working fluid may be desirable where, e.g., it is not necessary to run the internal combustion engine, and/or the internal combustion engine is running but for another purpose, e.g., to provide propulsion for the vehicle.

In a particularly preferred embodiment, the piston or pistons can also or instead (and preferably also) be driven by both internal combustion and the heated working fluid (e.g. steam) simultaneously, each acting on opposite sides of the piston or pistons in an appropriate cycle. In this case, the power stroke of the working fluid (e.g. steam) cycle is preferably synchronised with the compression stroke of the internal combustion cycle. The actual stroke sequence can be arranged as desired. For example, two working fluid (e.g. steam) expansions per one internal combustion cycle, or a single expansion of working fluid per one internal combustion cycle, could be used.

In these arrangements, the driven pistons could be used to provide mechanical power directly for a vehicle. However, in a preferred embodiment, the motion of the piston or pistons is used to generate electricity (which electricity may then be used, e.g., to drive wheel motors of (provide propulsion for) the vehicle, e.g. through an appropriate control circuit, power auxiliary electrical units of the vehicle and/or to charge a battery arrangement of the vehicle). This arrangement could also be used, e.g., as a stationary power generation unit, and in other engine applications, such as in trains and marine vessels.

Thus, according to a seventh aspect of the present invention, there is provided a power supply system, comprising:

an internal combustion engine;

means for using exhaust heat from the internal combustion engine to heat a working fluid; and

a piston arrangement that may be driven by both the internal combustion engine and the heated working fluid.

According to an eighth aspect of the present invention, there is provided a method of operating a power supply system that comprises an internal combustion engine, means for using exhaust heat from the internal combustion engine to heat a working fluid, and a piston arrangement, the method comprising:

driving the piston arrangement using both the internal combustion engine and the heated working fluid.

As will be appreciated by those skilled in the art, these aspects and embodiments of the invention may include any one or more or all of the preferred and optional features of the invention described herein. Thus, for example, the working fluid is preferably water, and it is preferably heated to generate steam to drive the piston arrangement. Similarly the piston arrangement can preferably be driven on one side by the internal combustion engine and on the other side by the working fluid and is preferably a free-piston arrangement. The piston arrangement can preferably be driven by the internal combustion engine alone, by the working fluid alone, and by the internal combustion engine and working fluid in combination. The arrangement is preferably used to generate electricity, e.g., and preferably, by the piston arrangement being used to drive a generator.

Where these aspects and arrangements of the invention are being used to generate electricity, then the electric generator can have any suitable and desired arrangement. However, in a particularly preferred embodiment a linear electric generator, preferably of a permanent magnet type is used, as that is particularly mechanically convenient for coupling to a linearly reciprocating piston arrangement. Indeed, it is, generally preferred in all arrangements and aspects of the present invention to use a linear electric generator, particularly where a linearly reciprocating piston arrangement is used (e.g. is to be driven by a working fluid, such as steam, generated in the manner of the present invention).

As will be appreciated by those skilled in the art, while the generation and storage of the heated working fluid in the manner of the present invention could be carried out continuously while, and whenever, the internal combustion engine of the vehicle is running, this is not essential and it could be carried out intermittently and/or as and when desired or required, if desired. For example, heated working fluid could be generated as and when required to maintain a suitable accumulated heated working fluid reserve, but not at other times, if desired.

It would also be possible to use the exhaust heat of the engine in other ways, in addition to using it to heat the working fluid. For example, the heat could be and preferably is also used to heat a thermoelectric generator, such as thermocouple or thermopile, or a similar solid state device, to generate electricity. This will further enhance the overall efficiency. Thus, in a preferred embodiment the heating of the working fluid is supplemented with solid state electricity generation, and the system of the present invention preferably comprises means for or a step of solid state electricity generation. It would also be possible, e.g., to use the, e.g., thermoelectric generator, to provide heating, e.g., of the exhaust catalyst, if desired.

Indeed, the Applicants believe that the use of a solid state electricity generation arrangement using the exhaust heat of the engine, together with using that heat to heat a working fluid, whether the heated working fluid is then stored for later use or simply used immediately, e.g., for electricity generation, may be advantageous, as it can provide a more efficient mechanism for extracting useful work from the rejected (waste) heat of the engine, than, e.g., simply heating a working fluid alone. In such an arrangement, a thermoelectric generator, such as a thermopile could be arranged in proximity to the exhaust system of the engine, together with a working fluid arrangement (e.g., and preferably, with the working fluid arrangement and exhaust system sandwiching the thermoelectric generator) so that both the thermoelectric generator and working fluid are heated by the hot exhaust of the engine.

Thus, according to a ninth aspect of the present invention, there is provided a power supply system, comprising:

an internal combustion engine;

means for heating a working fluid using exhaust heat from the internal combustion engine; and

a solid-state electricity generation arrangement that may be driven by exhaust heat from the internal combustion engine.

According to a tenth aspect of the present invention, there is provided a method of operating a power supply system comprising an internal combustion engine, a working fluid system, and a solid-state electricity generation arrangement, the method comprising:

heating the working fluid using exhaust heat from the internal combustion engine; and

heating the solid-state electricity generation arrangement using exhaust heat from the internal combustion engine.

As will be appreciated by those skilled in the art, these aspects and arrangements of the present invention can and preferably do include any one or more or all of the preferred and optional features of the invention described herein. Thus, for example, the solid state electricity generation arrangement is preferably a thermoelectric generator, and preferably a thermopile. Similarly, the working fluid is preferably water, the heated working fluid is preferably stored for later use (although this is not essential, and it could, as discussed above, be used immediately), and the working fluid is preferably used for electricity generation. Equally, the solid-state electricity generator (e.g. thermopile) and working fluid are preferably heated by the exhaust system (by heat transfer from the exhaust system) of the engine, and most preferably the arrangement is such that the working fluid heating arrangement sandwiches the solid state electricity generation arrangement (e.g. thermoelectric generator) against the exhaust system, whereby both the working fluid and the solid state electricity generator arrangement may be heated by the waste (rejected) heat from the exhaust system.

The internal combustion engine in the power supply system of the present invention can be any suitable such engine, such as a diesel or petrol engine. It is preferably a reciprocating engine.

The system of the present invention can be applied to any suitable vehicle and engine arrangement. It is particularly applicable to road vehicles, and so in a preferred embodiment, the system is for and/or on or in a road vehicle. Most preferably the system of the present invention is used for heavy vehicles, such as trucks, and for motor homes and luxury cars.

This said, arrangements of the present invention could also be used as stationary power generation units, and in other engine applications, such as trains and marine vessels.

As will be appreciated by those skilled in the art, all of the aspects and embodiments of the invention described herein may and preferably do include any one or more, or all of the preferred and optional features, of the invention described herein, as appropriate.

The methods in accordance with the present invention may be implemented at least partially using software e.g. computer programs. It will thus be seen that when viewed from further aspects the present invention provides computer software specifically adapted to carry out a method or the methods herein described when installed on data processing means, a computer program element comprising computer software code portions for performing a method or the methods herein described when the program element is run on data processing means, and a computer program comprising code means adapted to perform all the steps of a method or of the methods herein described when the program is run on a data-processing system. The invention also extends to a computer software carrier comprising such software which when used to operate a power supply system comprising data processing means causes in conjunction with said data processing means said system to carry out the steps of the method of the present invention. Such a computer software carrier could be a physical storage medium such as a ROM chip, CD ROM or disk, or could be a signal such as an electronic signal over wires, an optical signal or a radio signal such as to a satellite or the like.

It will further be appreciated that not all steps of the method of the invention need be carried out by computer software and thus from a further broad aspect the present invention provides computer software and such software installed on a computer software carrier for carrying out at least one of the steps of the methods set out herein.

The present invention may accordingly suitably be embodied as a computer program product for use with a computer system. Such an implementation may comprise a series of computer readable instructions either fixed on a tangible medium, such as a computer readable medium, for example, diskette, CD-ROM, ROM, or hard disk; or transmittable to a computer system, via a modem or other interface device, over either a tangible medium, including but not limited to optical or analogue communications lines, or intangibly using wireless techniques, including but not limited to microwave, infrared or other transmission techniques. The series of computer readable instructions embodies all or part of the functionality previously described herein.

Those skilled in the art will appreciate that such computer readable instructions can be written in a number of programming languages for use with many computer architectures or operating systems. Further, such instructions may be stored using any memory technology, present or future, including but not limited to, semiconductor, magnetic, or optical, or transmitted using any communications, technology, present or future, including but not limited to optical, infrared, or microwave. It is contemplated that such a computer program product may be distributed as a removable medium with accompanying printed or electronic documentation, for example, shrink-wrapped software, pre-loaded with a computer system, for example, on a system ROM or fixed disk, or distributed from a server or electronic bulletin board over a network, for example, the Internet or World Wide Web.

A number of preferred embodiments of the present invention will now be described by way of example only and with reference to the accompanying drawings, in which:

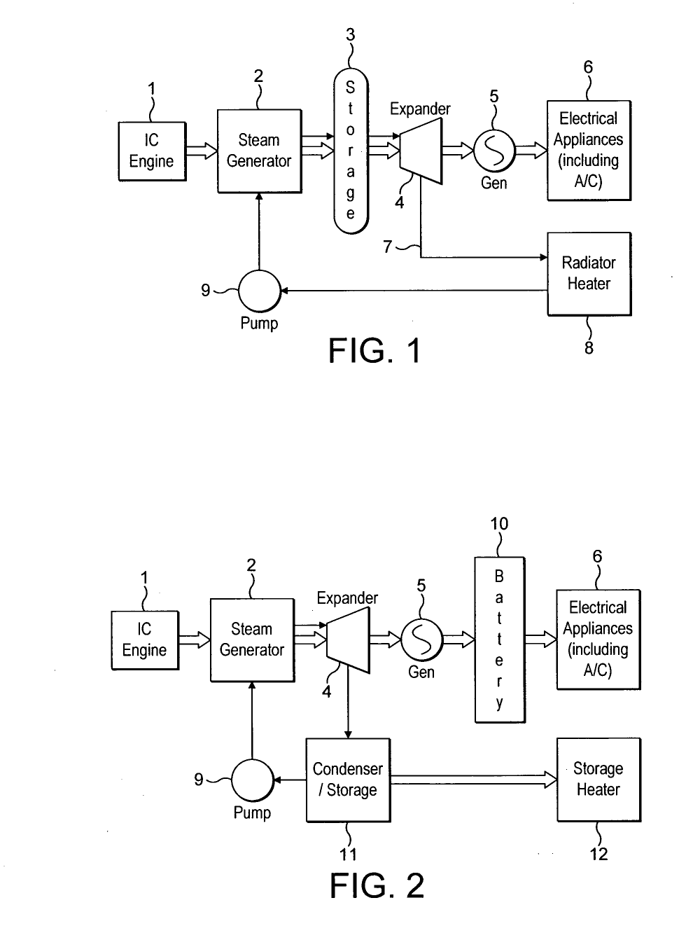

FIG. 1 shows schematically a first embodiment of a power supply system that is in accordance with the present invention;

FIG. 2 shows schematically a second embodiment of a power supply system that is in accordance with the present invention;

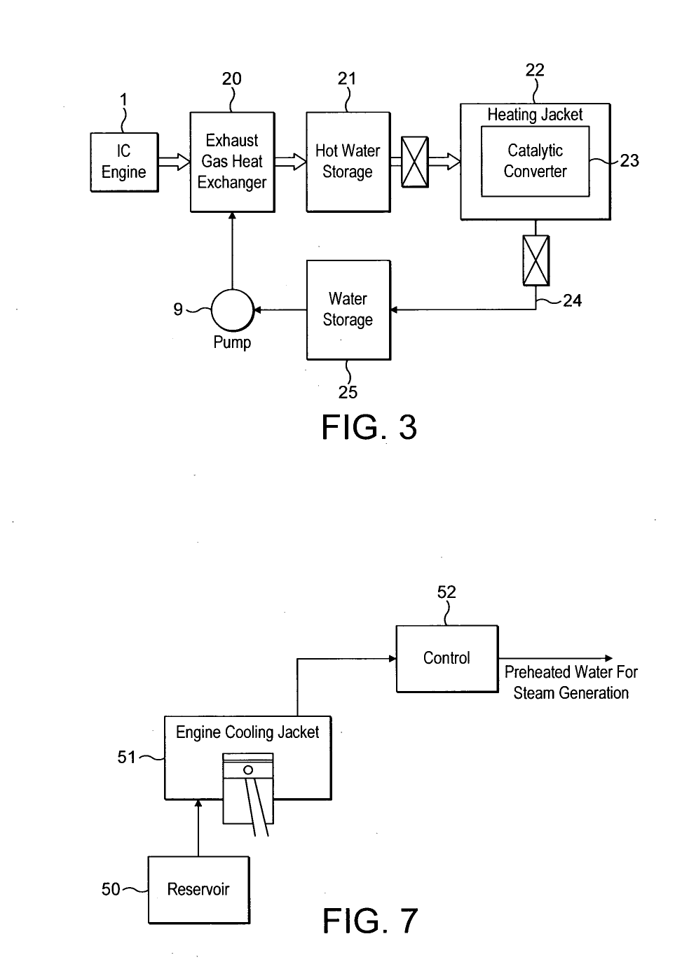

FIG. 3 shows schematically a third embodiment of a power supply system that is in accordance with the present invention;

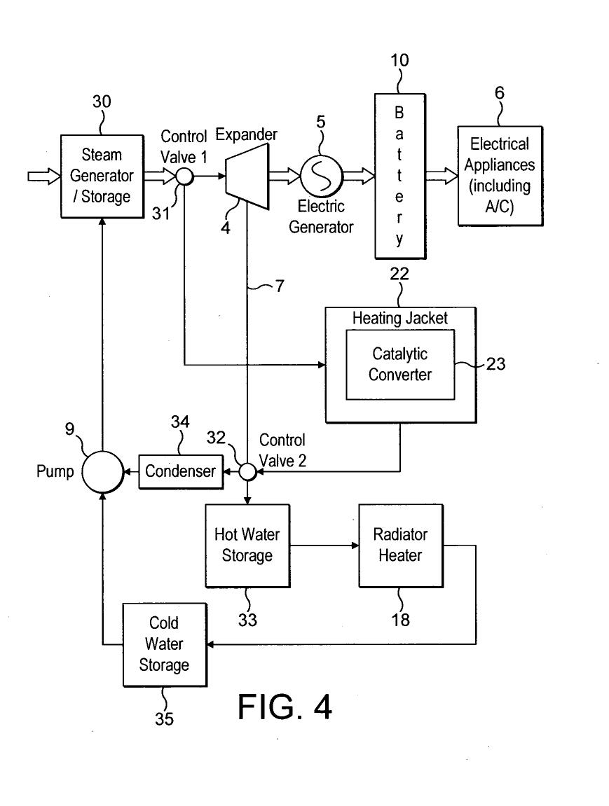

FIG. 4 shows schematically a fourth embodiment of a power supply system that is in accordance with the present invention;

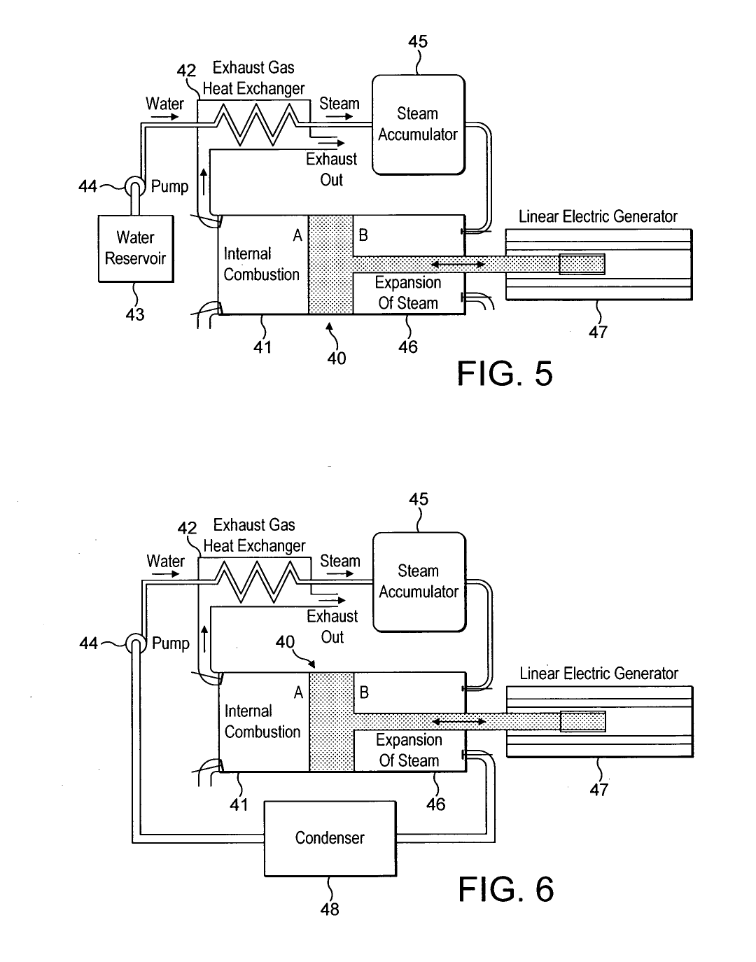

FIG. 5 shows schematically a fifth embodiment of a power supply system that is in accordance with the present invention;

FIG. 6 shows schematically a sixth embodiment of a power supply system that is in accordance with the present invention; and

FIG. 7 shows schematically an arrangement for preheating water that can be used in the present invention.

Like reference numerals are used for like components throughout the Figures.

The following preferred embodiments of the invention are all described with reference to the use of water as the working fluid that is heated and used. However, as will be appreciated by those skilled in the art, and as discussed above, the present invention is not limited to the use of water as the working fluid and other working fluids, such as a suitable organic fluid, such as iso-pentane or R245ca, could be used instead or as well, if desired. In this case, the system will operate in an analogous fashion, but with the alternative working fluid substituted for the water (and/or steam).

FIG. 1 shows schematically a first embodiment of a power supply system for a road vehicle, such as a truck, that is in accordance with the present invention.

The power supply system shown in FIG. 1 comprises an internal combustion engine 1. The exhaust heat from the internal combustion engine 1 when it is running is used to heat a working fluid, which in this case is water, in a steam generator system 2 to generate steam. The steam that is produced is stored in a storage tank 3 for later use, for example when the internal combustion engine 1 is not running.

When it is desired to use the stored steam from the storage tank 3, the steam is provided to an expander 4 to drive a generator 5 that generates electricity for running the electrical appliances 6, such as the air conditioning, of the vehicle.

The hot exhaust 7 from the expander 4 is used to drive a radiator heater 8 for cabin heating.

A pump 9 is provided to return the water from the radiator heater 8 to the steam generator 2 for reuse.

This arrangement provides a power supply system that can recover exhaust heat from the internal combustion engine 1, store it (in the form of steam), and then use it, e.g., to meet later vehicle hotel load demands.

A second preferred embodiment of the present invention is shown schematically in FIG. 2.

This embodiment is similar to the embodiment shown in. FIG. 1, but in this embodiment the generated steam is used immediately to drive an expander to generate electricity, and it is the hot exhaust from the expander that is stored for later use for heating.

Thus, as shown in FIG. 2, there is again an internal combustion engine 1 and a steam generator 2 that uses the hot exhaust from the internal combustion engine 1 to generate steam. In this case, the steam generated by the steam generator 2 is fed directly to an expander 4 which drives a generator 5 to generate electricity which is used to charge a battery 10 that can then be used to power the electrical appliances 6 of the vehicle.

Again, the hot exhaust steam 7 from the expander 4 is collected, but in this case it is condensed and stored as hot water in a condenser/storage unit 11. The stored hot water in the storage unit 11 can be provided to a storage heater 12 for the vehicle's cabin as and when desired. A gravity feeding mechanism or a small electric pump driven by the battery 10 is used to drive this heating system.

Again, a pump 9 is used to return water from the condenser/storage unit 11 to the steam generator 2 for reuse, as appropriate.

Various alternatives to this arrangement would be possible. For example, the generated steam could be used to run an absorption cycle air conditioning system, with the heat being supplied by the generated steam. The heater 12 could be fireless boiler technology based. The expander 4 could be used, for example, also or instead to feed back into the power supply system for vehicle propulsion.

A third preferred embodiment of a power supply system that is in accordance with the present invention is shown in FIG. 3.

In this embodiment the exhaust heat from the internal combustion engine is used to generate hot water which is then stored for use to heat the catalytic converter of the vehicle. (As is known in the art, the efficiency of exhaust gas after-treatment catalysts depends on the catalyst temperature. When the engine is started from cold, it takes some time for the catalyst to warm up to its operating temperature and until such time the catalyst does not function properly. By using steam generated by exhaust gas heat recovery to initially warm up the catalyst, the catalyst light-off-time, and hence exhaust emissions, can be reduced.)

As shown in FIG. 3, in this embodiment the exhaust heat from the internal combustion engine 1 is again used in an exhaust gas heat exchanger arrangement 20 to heat water. The heated water is then stored under pressure in an insulated hot water storage vessel (reservoir) 21. The stored hot fluid is released to the heating jacket 22 of the catalytic converter 23 when the ignition switch is turned on. The actuation is done through an electric switch that actuates the hot water circulation around the catalyst. The ignition of the engine is delayed until the catalyst 23 is warmed up.

The exhaust fluid 24 from the catalyst heating jacket 22 is collected and stored in a water storage tank 25, and then returned via pump 9 to the exhaust gas heat exchanger 20 to generate new, hot water as and when required.

FIG. 4 shows a further preferred embodiment of the present invention that combines the functions of the above-described embodiments.

In this embodiment the hot exhaust gases from the internal combustion engine (not shown) are again used to generate steam in an exhaust gas heat exchanger steam generator 30. The steam is generated and then stored at high pressure (5 to 50 bar) in the steam generator and storage system 30. The steam storage reservoir 30 is thermally lagged so that the steam can still be used several hours after main engine shutdown.

Steam from the steam reservoir 30 can be provided via a first control valve 31 to an electricity generating arrangement comprising a steam expander 4 (which may, e.g., be a rotary or reciprocating expander) that drives an electric generator 5. The generated electricity is used to charge a battery 10 that can then be used to power electrical appliances 6 of the vehicle, and, for example, to meet hotel load demands and as an auxiliary power unit for the vehicle.

In this embodiment, electricity is generated continuously by this means when the internal combustion engine (primary engine) is running. Electricity can also be generated (and stored) in this manner using steam stored in the steam reservoir 30 when the internal combustion engine is not running.

The exhaust steam (hot condensate) 7 from the expander 4 is sent via a second control valve 32 either to a thermally-lagged hot water storage reservoir 33 (from where it can then be used, as will be discussed below, to, e.g., heat the vehicle cabin through a radiator when the main engine is not running), or into a condenser 34 that passes the condensate (water) to a pump 9 that completes the continuous circuit (cycle) by pumping the liquid back to the steam generator and storage system 30. The latter arrangement is used when the hot water storage 33 is filled with a predetermined capacity,.i.e. such that when the hot water storage 33 is filled with a predetermined capacity, the steam bypasses the hot water storage 33 and instead runs through a continuous cycle (such that, for example, a continuous steam circuit and electricity generation will then take place when the internal combustion engine is running).

As discussed above, the hot liquid stored in the hot water storage reservoir 33 can be sent through a radiator heater 8 to provide vehicle cabin heating. The output from the radiator heater 8 is either stored in a cold water storage tank 35, or provided to the pump 9 to run through a continuous cycle. The continuous cycle is used when the internal combustion engine is running. Otherwise, the exhaust water from the radiator heater 8 is stored in the cold water storage 35 until more steam generation is required.

Hot steam from the steam generator/storage system 30 can be bled into the hot water storage reservoir 33 on demand, to make up the hot water storage reservoir 33, for example in the case of low temperature in the hot water storage reservoir 33. This enables the temperature of the radiator heater 8 to be maintained at a desired set level.

As well as the above arrangements for generating electricity and providing cabin heating, the system of this embodiment can also be used to provide heating of the catalyst in the vehicle's catalytic converter, in a similar manner to that described above with reference to FIG. 3.

Thus, as shown in FIG. 4, the steam generated and stored in the steam generator and storage system 30 can also be used to heat and regulate the temperature of the catalyst 23 of the vehicle by releasing the required amount of steam/water from the steam generator/storage system 30 at high pressure via the control valve 31 to the heating coils 22 of the catalytic converter 23. This is done initially to heat the catalyst before start-up of the internal combustion engine (to reduce the catalyst's light-off time). Thereafter, the temperature of the catalyst 23 is regulated by regulating the flow of hot steam through the heating coils 22 using the first control valve 31 and second control valve 32. Temperature regulation of the catalyst 23 is achieved by controlling the pressure and flow of steam through the heating circuit 22.

Again, the exhaust steam from the catalyst heating coils 22 can be provided by the control valve 32 either to the hot water storage vessel 33 to be available for cabin heating purposes, or be recirculated immediately via condenser 34 and pump 9.

Another preferred embodiment of the present invention will now be described with reference to FIG. 5.

This embodiment comprises a free-piston engine having a double acting free-piston arrangement that goes through a conventional internal combustion cycle (e.g. an Otto or Diesel cycle) on one side of the piston and a steam expansion cycle (e.g. a Rankine steam expansion cycle) on the other side of the piston, and can be used, for example, to generate electricity.

Thus, as shown in FIG. 5, the piston 40 of this arrangement has one side 41 that is driven by an internal combustion cycle, working, for example, on the Otto or Diesel cycle. It can be driven by either a two-stroke or four-stroke cycle.

The exhaust gas from the internal combustion engine cycle is fed to an exhaust gas heat exchanger 42 where it heats water from a water reservoir 43 (that is provided via a pump 44 to the exhaust gas heat exchanger 42) to generate steam. The generated steam is stored in a steam accumulator 45.

The steam from the steam accumulator 45 can be provided to the reverse side 46 of the piston 40 and be expanded in the reverse side 46 of the piston 40 to drive the piston in a Rankine steam cycle.

A U-flow valve operated induction and exhaust is :used for the steam cycle, as this allows greater precision and control. However, a uniflow steam expansion could be used if desired.

The piston 40 is used to drive a linear electric generator 47. This linear electric generator 47 is of a permanent magnet type, although other arrangements would be possible. The electricity generated can be used, for example, to drive wheel motors of a vehicle through an appropriate control circuit and/or to charge a battery or drive electrical systems of a vehicle. The arrangement could also be used as a stationary power generation unit and in other engine applications, such as trains and marine vessels.

In this embodiment, the piston 40 can be driven by the internal combustion engine alone, by the steam alone, or by the internal combustion engine and steam cycle operating together.

In the case of operation using the internal combustion engine alone, the internal combustion engine side 41 of the piston 40 is propelled by the hot products of combustion, as is known in the art. In this case both the valves of the steam side 46 of the piston are kept closed to produce spring action to move the piston backwards. This arrangement may be useful, for example, when starting the engine, and when there is not enough steam to operate the steam side of the piston.

In the case of driving the piston 40 using steam only, the valves on the internal combustion engine side 41 of the piston 40 are closed, and the steam side 46 of the piston 40 is driven using steam stored in the steam accumulator 45. (It would also be possible with an appropriate arrangement of valves to provide steam to both sides 41 and 46 of the piston 40, if desired.)

When using both the internal combustion engine and the steam cycles to drive the piston 40, then the internal combustion engine side 41 of the piston 40 is driven by hot products of combustion from the internal combustion engine, and the steam side 46 of the piston is driven by steam from the steam accumulator 45 (generated by the exhaust gas heat exchanger 42). Two steam expansions per one internal combustion engine cycle or a single expansion of steam per internal combustion cycle can be used. The power stroke of the steam cycle is synchronised with the compression stroke of the internal combustion cycle.

The arrangement shown in FIG. 5 has an open loop steam cycle, i.e. such that the exhaust steam is simply exhausted to the atmosphere.

It would also be possible to have a closed loop steam cycle, in which the exhausted steam from the steam side 46 of the piston 40 is collected and returned to the exhaust gas heat exchanger for use to generate more steam. FIG. 6 shows such an arrangement. In this case, the only change from the arrangement shown in FIG. 5 is that the exhaust steam from the steam side 46 of the piston 40 is recirculated via a condenser 48 to the pump 44 for returning to the exhaust gas heat exchanger 42 for the generation of more steam.

As will be appreciated by those skilled in the art, various modifications and changes can be made to the above embodiments of the invention, as appropriate, and if desired.

For example, the water to be used for the generation of steam could be preheated by first circulating it around the internal combustion engine, before providing it to the exhaust gas heat exchanger (steam generation) system. FIG. 7 shows schematically such an arrangement. In this case, water from a water reservoir, 50 is provided to an engine cooling jacket arrangement 51 which, in effect, will preheat the water, for example to near 100° C. The water is then passed from the engine cooling jacket circuit 51 via an appropriate control mechanism 52 to, for example, another water reservoir ready for steam generation, or directly to the exhaust gas heat steam generation arrangement.

As can be seen from above, the present invention in its preferred embodiments at least comprises an arrangement whereby exhaust heat from the main internal combustion engine in a vehicle can be recovered while the main engine is running, stored, and then used later to meet, e.g., hotel load demands of the vehicle. The recovered heat energy can also be used for catalyst heating and power generation and storage. This facilitates, for example, reductions in engine idling time and the need to idle engines to meet hotel load demands, for example for heavy vehicles such as trucks and for luxury cars and motor homes, with commensurate reductions in, for example, emissions and noise pollution.

1. A power supply system for a vehicle that includes an internal combustion engine, the system comprising:
means for recovering exhaust heat when the internal combustion engine is running;
means for storing the recovered heat energy at least in part as heat energy; and
means for providing the stored heat energy at a later time to provide heat and/or power for the vehicle.

2. The system of claim 1, wherein:
the means for recovering exhaust heat comprises means for heating a working fluid using the exhaust heat from the internal combustion engine; and
the means for storing the recovered heat energy comprises a means for storing the heated working fluid.

3. A power supply system for a vehicle that includes an internal combustion engine, the system comprising:
means for using exhaust heat from the internal combustion engine to heat a working fluid; and
means for storing the heated working fluid whereby it may be used to provide heat and/or power for the vehicle at a later time.

4. The system of claim 2 or 3, comprising:
means for using the engine exhaust and/or engine exhaust gases to heat the working fluid.

5. The system of claim 2, 3 or 4, comprising:
means for circulating the working fluid around or over the internal combustion engine, whereby the working fluid is heated by the engine in use.

6. The system of any one of claims 2 to 5, further comprising:
a working fluid supply from which fluid can be provided to be heated, and wherein the heated working fluid is returned to the working fluid supply once used.

7. The system of any one of claims 2 to 6, wherein the heated working fluid is stored in gaseous form.

8. The system of any one of claims 2 to 7, wherein the heated working fluid is stored in liquid form.

9. The system of any one of claims 2 to 8, further comprising:
a piston arrangement that may be driven by both the internal combustion engine and the heated working fluid in a gaseous form,

10. A power supply system, comprising:
an internal combustion engine;
means for using exhaust heat from the internal combustion engine to heat a working fluid; and
a piston arrangement that may be driven by both the internal combustion engine and the heated working fluid in a gaseous form.

11. The system of claim 9 or 10, wherein the piston arrangement is driven on one side by the internal combustion engine and driven on the other side by the working fluid.

12. The system of claim 9, 10 or 11, further comprising:
an electric generator driven by the piston arrangement.

13. The system of any one of the preceding claims, further comprising:
means for using the stored heat energy or stored heated working fluid to generate electricity.

14. The system of any one of the preceding claims, further comprising:
means for using the stored heat energy or stored heated working fluid to heat the catalyst of a catalytic converter exhaust gas treatment arrangement of the vehicle.

15. A system for an internal combustion engine of a vehicle which includes a catalytic converter exhaust gas treatment arrangement, the system comprising:
means for using exhaust heat from the internal combustion engine to heat a working fluid; and
means for using the heated working fluid to heat the catalyst of the exhaust gas treatment arrangement.

16. The system of any one of the preceding claims, further comprising:
a solid-state electricity generation arrangement that may be driven by exhaust heat from the internal combustion engine.

17. A power supply system, comprising:
an internal combustion engine;
means for heating a working fluid using exhaust heat from the internal combustion engine; and
a solid-state electricity generation arrangement that may be driven by exhaust heat from the internal combustion engine.

18. The system of claim 16 or 17, wherein the solid-state electricity generation arrangement is a thermoelectric generator.

19. The system of any one of the preceding claims, comprising:
an internal combustion engine.

20. The system of any one of claims 2 to 19, wherein the working fluid is water.

21. The system of claim 20, wherein the heated water is stored at least in part in the form of steam.

22. The system of claim 20 or 21, wherein the heated water is stored at saturation condition.

23. A method of operating a power supply for a vehicle that includes an internal combustion engine, the method comprising:
recovering exhaust heat when the internal combustion engine is running;
storing the recovered heat energy at least'in part as heat energy; and
providing the stored heat energy at a later time to provide heat and/or power for the vehicle.

24. The method of claim 23, wherein:
the step of recovering exhaust heat comprises using the exhaust heat to heat a working fluid; and
the step of storing the recovered heat energy comprises storing the heated working fluid.

25. A method of operating a power supply system for a vehicle that includes an internal combustion engine, the method comprising:
using exhaust heat from the internal combustion engine to heat a working fluid; and
storing the heated working fluid whereby it may be used to provide heat and/or power for the vehicle at a later time.

26. The method of claim 24 or 25, comprising: heating the working fluid using the engine exhaust and/or engine exhaust gases.

27. The method of claim 24, 25 or 26, comprising:
heating the working fluid by circulating the fluid around or over the internal combustion engine whilst the engine is in use.

28. The method of claim 24, 25, 26 or 27, comprising:
preheating the working fluid by circulating the fluid around or over the internal combustion engine whilst the engine is in use before heating the working fluid using the engine exhaust and/or engine exhaust gases.

29. The method of any one of claims 24 to 28, further comprising:
supplying the fluid to be heated from a working fluid supply; and
returning the heated working fluid to the working fluid supply once used.

30. The method of any one of claims 24 to 29, further comprising:
storing the heated working fluid in gaseous form.

31. The method of any one of claims 24 to 30, further comprising:
storing the heated working fluid in liquid form.

32. The method of any one of claims 24 to 31, further comprising:
driving a piston arrangement using both the internal combustion engine and the heated working fluid in a gaseous form.

33. A method of operating a power supply system comprising an internal combustion engine, a working fluid system, and a piston arrangement, the method comprising:
heating the working fluid using exhaust heat from the internal combustion engine; and
driving the piston arrangement using both the internal combustion engine and the heated working fluid in a gaseous form.

34. The method of claim 32 or 33, wherein the piston arrangement is driven on one side by the internal combustion engine and driven on the other side by the working fluid.

35. The method of claim 32, 33 or 34, further comprising:
generating electricity by driving an electricity generator using the piston arrangement.

36. The method of any one of claims 23 to 35, further comprising:
using the stored heat energy or stored heated working fluid to provide heat and/or power for the vehicle without the simultaneous operation of the internal combustion engine.

37. The method of any one of claims 23 to 36, further comprising:
generating electricity using the stored heat energy or stored heated working fluid.

38. The method of any one of claims 23 to 37, further comprising:
using the stored heat energy or stored heated working fluid to heat the catalyst of a catalytic converter exhaust gas treatment arrangement of the vehicle.

39. A Method of operating an engine system of a vehicle which includes an internal combustion engine and a catalytic converter exhaust gas treatment arrangement, the method comprising:
using exhaust heat from the internal combustion engine to heat a working fluid; and
using the heated working fluid to heat the catalyst of the exhaust gas treatment arrangement.

40. The method of any one of claims 23 to 39, further comprising:
heating a solid-state electricity generation arrangement using exhaust heat from the internal combustion engine

41. A method of operating a power supply system comprising an internal combustion engine, a working fluid system, and a solid-state electricity generation arrangement, the method comprising:
heating the working fluid using exhaust heat from the internal combustion engine; and
heating the solid-state electricity generation arrangement using exhaust heat from the internal combustion engine.

42. The method of claim 40 or 41, wherein the solid-state electricity generation arrangement is a thermoelectric generator.

43. The method of any one of claims 23 to 42, wherein the working fluid is water.

44. The method of claim 43, comprising storing the heated water at least in part in the form of steam.

45. The method of claim 43 or 44, comprising storing the heated water at saturation condition.

46. A vehicle including the system of any one of claims 1 to 22, or operated in accordance with the method of any one of claims 23 to 45.

47. A computer program element comprising computer software code portions for performing the method of any one of claims 23 to 45 when the program element is run on data processing means.

48. A power supply system substantially as herein described with reference to any one of the accompanying drawings.

49. A system for an internal combustion engine of a vehicle as herein described with reference to any one of the accompanying drawings.

50. A method of operating a power supply system as herein described with reference to any one of the accompanying drawings.

51. A method of operating an engine system of a vehicle as herein described with reference to any one of the accompanying drawings.

52. A vehicle as herein described with reference to any one of the accompanying drawings.
